(19) United States
(12) Patent Application Publication
(10) Pub. No.: US 2026/0053051 A1
(43) Pub. Date: Feb. 19, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Yi-Chen Li, Taichung City (TW); Jen-Yuan Chang, Hsinchu City (TW)

(73) Assignee: Taiwan Semiconductor Manufacturing Company, Ltd., Hsinchu (TW)

(21) Appl. No.: 18/808,059

(22) Filed: Aug. 18, 2024

(51) Int. Cl. H01L 23/31; H01L 21/3065; H01L 21/56; H01L 23/00; H01L 25/00; H01L 25/065; H01L 29/06

(52) U.S. Cl. CPC H01L 23/3135; H01L 24/08; H01L 25/0657; H01L 25/50; H10D 62/117; H01L 21/3065; H01L 21/56

(57) ABSTRACT

A semiconductor structure, including a first semiconductor structure, a second semiconductor structure, and a filling material is disclosed. The first semiconductor structure has a first surface and a second surface opposite to the first surface. The first semiconductor structure has a body portion and a semiconductor brim portion protruded from the body portion. The semiconductor brim portion is closer to the second surface. The second semiconductor structure is in contact with the first surface of the first semiconductor structure and bonded with the first semiconductor structure. The filling material surrounds the first semiconductor structure and is filled between the semiconductor brim portion and the second semiconductor structure. The filling material wraps around and covers the semiconductor brim portion, and a sidewall of the filling material is aligned with a sidewall of the second semiconductor structure.

### BACKGROUND

Together with various semiconductor manufacturing processes, it is essential to establish reliable bonding and electrical inter-connection among the semiconductor structures incorporating wafers, different types of semiconductor chips/dies and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9 illustrate schematic cross-sectional views of various stages of a manufacturing method of a semiconductor structure, in accordance with some embodiments of the present disclosure.

FIGS. 10A-10C are schematic top views of exemplary die structures after performing a pruning process in accordance with some embodiments of the present disclosure.

FIGS. 11A-11H are schematic top views of corner portions of the exemplary pruned die structures in accordance with some embodiments of the present disclosure.

FIG. 12A is a schematic top view of an exemplary pruned die structure after performing a pruning process in accordance with some embodiments of the present disclosure.

FIGS. 12B-12D are schematic cross-sectional views of different edge portions of the exemplary pruned die structure in accordance with some embodiments of the present disclosure.

FIG. 13A is a schematic top view of an exemplary enfolded die structure after performing an enfolding process in accordance with some embodiments of the present disclosure.

FIGS. 13B-13D are schematic cross-sectional views of different edge portions of the exemplary enfolded die structure in accordance with some embodiments of the present disclosure.

FIG. 14 illustrates a schematic cross-sectional view of a bonded semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the present disclosure provides applicable concepts that can be embodied in a wide variety of specific contexts. The specific embodiment(s) discussed herein is merely illustrative and is related to a three-dimensional (3D) integration structure or assembly, and does not limit the scope of the present disclosure. Embodiments of the present disclosure describe the exemplary manufacturing process of 3D stacking structures and the 3D stacking structures fabricated there-from. Certain embodiments of the present disclosure are related to the 3D stacking structures formed with wafer bonding structures and stacked wafers and/or dies. Other embodiments relate to 3D integration structures or assemblies including post-passivation interconnect (PPI) structures or interposers with other electrically connected components, including wafer-to-wafer assembled structures, die-to wafer assembled structures, package-on-package assembled structures, die-to-die assembled structures, and die-to-substrate assembled structures. The wafers or dies may include one or more types of integrated circuits or electrical components on a bulk semiconductor substrate or a silicon/germanium-on-insulator substrate. The embodiments are intended to provide further explanations but are not used to limit the scope of the present disclosure.

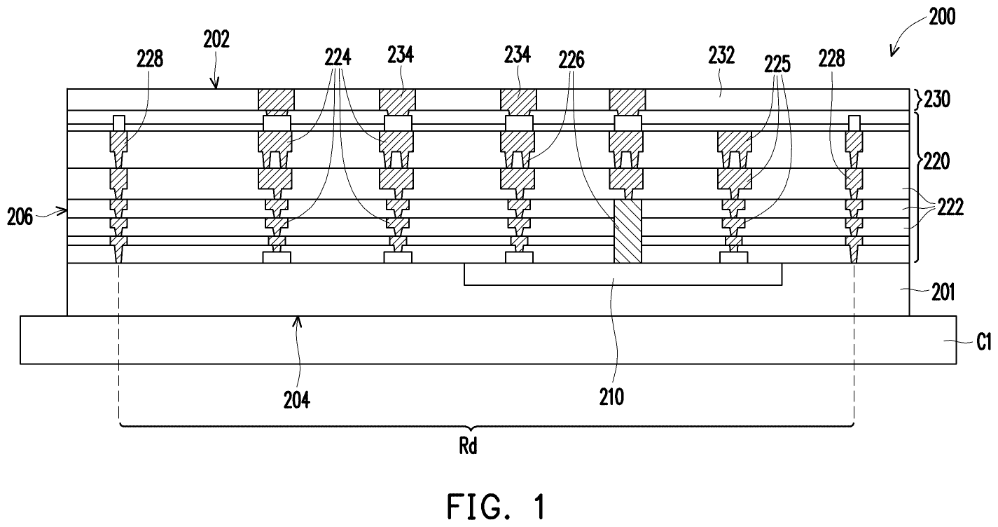

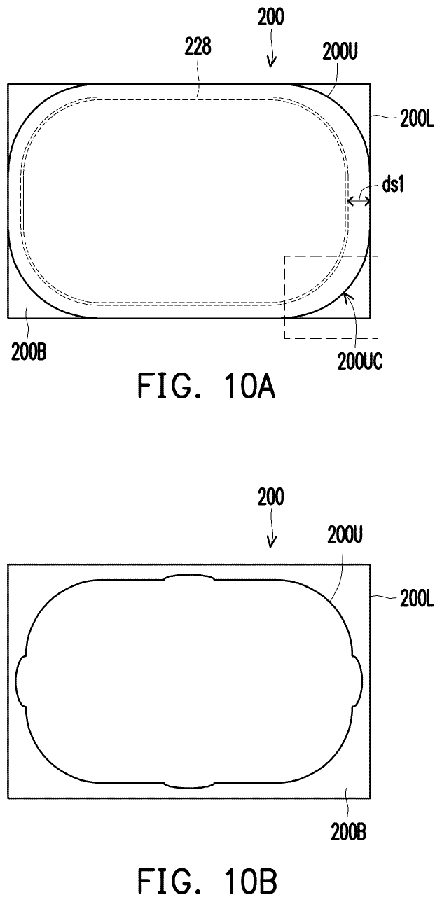

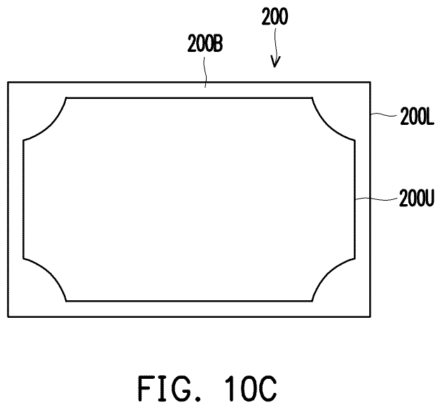

FIGS. 1-9 illustrate schematic cross-sectional views of various stages of a manufacturing method of a semiconductor structure, in accordance with some embodiments of the present disclosure. FIGS. 10A-10C are schematic top views of exemplary die structures after performing a pruning process in accordance with some embodiments of the present disclosure.

Referring to FIG. 1, a first die 200 is provided on a carrier C1. In some embodiments, the carrier C1 may be a carrier wafer of any appropriate size and shape. In some embodiments, the carrier C1 functions as a temporary carrier with a de-bonding layer (not shown) thereon for temporarily joining and later detaching the carried structure. In some embodiments, the carrier C1 is or includes a semiconductor bulk wafer of a round or oval shape.

Referring to FIG. 1, a first die 200 that has a first surface 202 and a second surface 204 opposite to the first surface 202 and sidewalls 206 connecting the first surface 202 and the second surface 204 is provided and fixed onto the carrier C1. In some embodiments, the first die 200 includes a semiconductor substrate 201, one or more device layers 210 embedded in the semiconductor substrate 201, an interconnection structure 220 formed on the semiconductor substrate 201, and a bonding layer 230 formed on the interconnection structure 220.

As the device layer 210 is located closer to the second surface 204, the second surface 204 may be referred to the backside surface of the first die 200, while the opposite first surface 202 may be referred to the frontside surface of the first die 200. In some embodiments, the sidewalls 206 in FIG. 1 are illustrated as upright vertical sidewalls (i.e. flat plane surfaces), it is possible that the sidewalls are slant sidewalls or curved sidewalls.

In some embodiments, the first die 200 is a semiconductor die fabricated and diced from a semiconductor wafer. In some embodiments, the first die 200 includes the semiconductor substrate 201 made of a semiconductor material including silicon, strained silicon, silicon alloy, silicon carbide, silicon-germanium, silicon-germanium carbide, germanium, germanium alloys, germanium arsenide, or group III-V semiconductors (e.g. gallium arsenide, gallium nitride, indium arsenide, etc.). In some embodiments, the first die 200 includes a semiconductor material and fabricated from a silicon bulk wafer, a silicon-on-insulator (SOI) wafer or a gallium arsenide wafer. In some embodiments, the first die 200 is a device die including a plurality of devices formed within the device layer(s) 210. In some embodiments, the devices formed within the device layer(s) 210 may include, for example, active devices (e.g., transistors, diodes, silicon-controlled rectifiers, generators, or the like) and optionally passive devices (e.g., resistors, capacitors, inductors, transducers, transformers or the like), or image sensors capable of converting light to electrical signals formed therein. In certain embodiments, the devices formed in the device layer(s) 210 may include, for example, transistors. In some embodiments, the device layer(s) 210 is located relatively distanced from the sidewalls 206 and located within the region(s) defined by the seal ring(s) 228 or the device region Rd of the first die 200, such that the following pruning process may be carried out without damaging the device layer(s) 210 or the devices therein. In some embodiments, additional semiconductor devices or electrical components with different functions or integrated circuits may also be included in the first die 200. In some embodiments, the interconnection structure 220 is electrically connected with the device layer(s) 210 of the first die 200 and is electrically coupled with the devices and/or other electrical components formed within the device layer(s) 210. The scope of the disclosure is not limited to the embodiments or drawings described therein.

In some embodiments, referring to FIG. 1, the interconnection structure 220 includes a plurality of dielectric layers 222 and a plurality of conductive patterns 224 alternately stacked. The conductive patterns 224 include routing traces 225 extending horizontally in between consecutively stacked dielectric layers 222 and vias 226 vertically penetrating through the dielectric layers 222 to establish electrical connection between the above and underlying routing traces and to the device layer(s) 210. In some embodiments, the interconnection structure 220 provides redistributing functions for routing, relocating or redistribution the electrical connection paths for the devices of the device layers 210. In some embodiments, the interconnection structure 220 includes seal rings 228 extending vertically through the dielectric layers 222 and functioning as structural supportive elements for reinforcing the structural rigidity during dicing or pruning. In some embodiments, the seal rings 228 are electrically floating elements. It is understood that the numbers and configurations of the dielectric layers 222 and the conductive patterns 224 are merely exemplary and not intended to limit the scope of this disclosure.

In some embodiments, referring to FIG. 1, the bonding layer 230 that is formed over the interconnection structure 220 includes a bonding dielectric layer 232 and bonding pads 234 embedded in the bonding dielectric layer 232. In some embodiments, the formation of the first bonding structure 230 involves forming the bonding dielectric layer 232 over and covering the interconnection structure 220, forming openings in the bonding dielectric layer 232 at specific locations, and forming bonding pads 234 in the openings of the bonding dielectric layer. In some embodiments, some of the bonding pads 234 are electrically connected with the devices formed in the device layers 210 by way of the interconnection structure 220 and other conductive elements formed in the first die 200.

Among various product structures, some large size dies may face warpage situations before bonding or assembly. In order to counterbalance the possible warpage situations, relative to the more planar central portion, the die structure may undergo a pruning process to remove the peripheral portion (i.e. the most deformed portion) of the die.

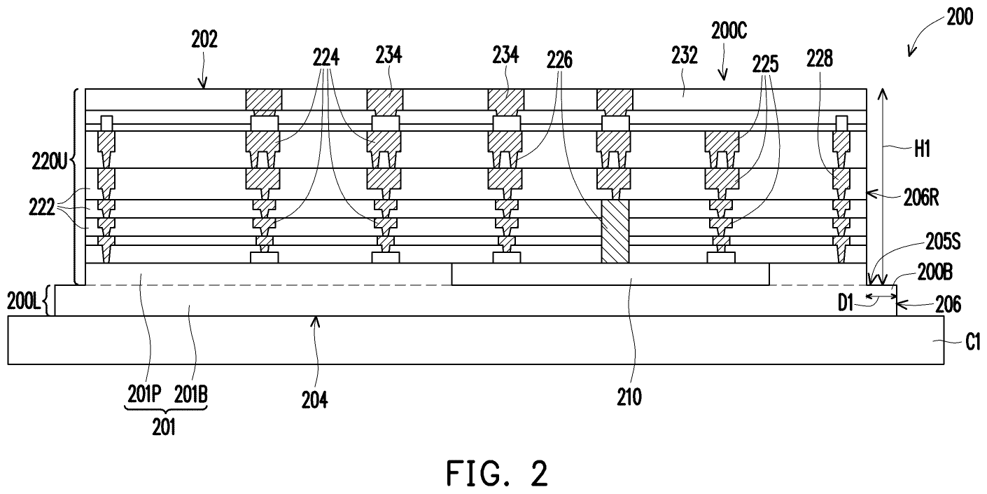

Referring to FIG. 2, in some embodiments, a pruning process is performed to the first die 200 to remove the outer edges (the border) or a peripheral portion of the first die 200. In some embodiments, the pruning process is performed with a trimming depth H1 and a trimming distance/width D1 to remove a peripheral portion of the first die 200. In some embodiments, the pruning process includes removing or trimming off a peripheral portion of the first die 200 from the surface 202, etching vertically downward (i.e. etching towards the opposite surface 204 but not etching through) along the thickness direction to a trimming depth H1. In some embodiments, as seen in FIG. 2, after performing the pruning process, the pruned first die 200 includes the upper recessed portion 200U with recessed sidewall(s) 206R and the lower remained portion 200L with the sidewalls 206. For example, the pruning process is performed to the first surface 202, cutting and penetrating through the bonding layer 230, through the interconnection structure 220 and removing a fringe portion of the semiconductor substrate 201 of the first die 200. Following the removal of the fringe portion of the semiconductor substrate 201, the semiconductor substrate 201 is pruned into a lower base substrate portion 201B and the pruned substrate portion 201P on the lower base substrate portion 201B. The length/width of the lower base substrate portion 201B is larger than the length/width of the pruned substrate portion 201P In some embodiments, a brim portion 200B that is protruded beyond the recessed sidewall(s) 206R is included in the lower base substrate portion 201B in the remained portion 200L of the pruned first die 200. In some embodiments, the brim portion 200B is made of a semiconductor material as it is formed from the semiconductor substrate 201 through the pruning process.

In some embodiments, using a rectangular or square shaped die as an example, the pruned first die 200 may be cross-sectionally shaped as a reverse bachelor cap (tassel free), the recessed portion 200U is a bung block portion located on and integrally joined with the underlying board portion, i.e. the remained portion 200L. In some embodiments, the brim portion(s) 200B is protruded outwardly from the body portion 200C of the pruned first die 200, and the width of the brim portion(s) 200B is measured from the recessed sidewall(s) 206R to the outermost edge of the brim portion(s) 200B. Referring to FIG. 2, the recess portion 200U is included in the body portion 200C, and the recess portion 200U includes the interconnection structure 220 and the bonding layer 230 and the pruned substrate portion 201P.

In some embodiments, the trimming depth H1 of the pruning process is larger than the total thickness of the interconnection structure 220 and the bonding layer 230. In some embodiments, depending on the warpage level and the product designs, the trimming depth and the trimming distance/width may be adjusted for the best warpage offset effects. In some embodiments, the range of the trimming depth H1 is about 0.0001% to about 90% of the thickness of the first die 200. In some embodiments, the range of the trimming depth H1 is about 1% to about 50% of the thickness of the first die 200. In some embodiments, the thickness of the first die ranges from about 5 microns to about 1000 microns. For example, the thickness of the first die ranges from about 7 microns to about 30 microns, and the trimming depth H1 ranges from about 2 microns to about 5 microns.

In some embodiments, the trimming distance/width D1 of the pruning process may range from about 10⁻⁶ % to about 0.05% of the width of the first die 200. In some embodiments, the trimming distance/width D1 of the pruning process may range from about 0.0001% to about 0.05% of the width of the first die 200. In some embodiments, the width of the first die ranges from about 0.3 cm to about 300 cm. For example, the width of the first die ranges from about 1 cm to about 3 cm, and the trimming distance/width D1 ranges from about 1 micron to about 20 microns.

It is appreciated that the trimming depth and/or the trimming width/distance may be modified depending on the dimension of the die or wafer and the design requirements of the product, which is not limited thereto.

In some embodiments, the pruning process is performed to the first die 200, etching from the first surface 202, penetrating through the bonding layer 230 and through the interconnection structure 220, and stopping at the semiconductor substrate 201 of the first die 200. In some embodiments, the trimming depth of the pruning process may be substantially equivalent to the total thickness of the interconnection structure 220 and the bonding layer 230. In such embodiments, the remained portion 200L mainly contains the semiconductor substrate 201, and the brim portion 200B is the protruded part of the remained portion 200L extended beyond the recessed sidewall(s) 206R of the pruned first die 200. Herein, the recess portion 200U includes the interconnection structure 220 and the bonding layer 230 only. For example, the thickness of the first die ranges from about 7 microns to about 30 microns, and the trimming depth ranges from about 1 micron to about 2 microns.

In some embodiments, the peripheral portion to be trimmed is limited to the outer portion located outside the seal ring(s) 228 without containing devices and electronic components and is basically defined by the distribution and location of the seal ring(s) 228. In some embodiments, the pruning process is limited to the non-device peripheral region to remove the peripheral portion, and the trimming distance/width D1 of the pruning process is limited by the size of the peripheral portion. That is, the portion removed by the pruning process is located outside the span of the seal ring(s) 228.

In some embodiments, the contour of the upper recessed portion 200U is located within the contour of the lower remained portion 200L but the upper recessed portion 200U is recessed from the lower remained portion 200L with different trimming distances/widths at various locations.

As seen in the schematic top view of FIG. 10A, the contour of the upper recessed portion 200U is located outside the span of the seal ring(s) 228 but is located inside the contour of the lower remained portion 200L. In some embodiments, the contour of the upper recessed portion 200U is located outside and spaced apart from the span of the seal ring(s) 228 with a distance ds1. Clearly, the cross-sectional area of the recessed portion 200U is smaller than that of the remained portion 200L, while the cross-sectional area of the remained portion 200L is substantially equivalent to that of the original and unpruned die 200. In some embodiments, the contour of the upper recessed portion 200U is located outside but approaching the span of the seal ring(s) 228. From the schematic top view of FIG. 10A, the contour of the upper recessed portion 200U is in a stadium shape or shaped as a rectangle with rounded corners. As seen in the top view of FIG. 10A, the brim portions 200B are located at four corners of the remained portion 200L and exposed from the recessed portion 200U that are located in the inner mid region of the first die 200. In FIG. 10A, for the corner portion (encircled by the dotted line), the contour of the rounded corner portion 200UC of the upper recessed portion 200U is in an arc shape.

Referring to the schematic top view of FIG. 10B, the contour of the upper recessed portion 200U is in a tray shape with wavy sides or shaped as a corner rounded rectangle with protrusions at four sides. As seen in the top view of FIG. 10B, the brim portion(s) 200B exposed from the recessed portion 200U is shaped as a continuous ring extending along the marginal region of the first die 200.

From the schematic top view of FIG. 10C, the contour of the upper recessed portion 200U is shaped as a rectangle with concave arc at four corners (concave arc corners). As seen in the top view of FIG. 10C, the brim portion(s) 200B exposed from the recessed portion 200U is shaped as a continuous ring extending along the marginal region of the first die 200.

Basically, the width of the brim portion(s) substantially equals to the trimming distance/width during the pruning process. Similarly, the thickness of the brim portion(s) plus the trimming depth during the pruning process is substantially equivalent to the thickness of the die. The shapes and the dimensions of the brim portion(s) may be fine tuned in response with the stress distribution for efficiently easing the non-bonding issues that may be caused by warpage.

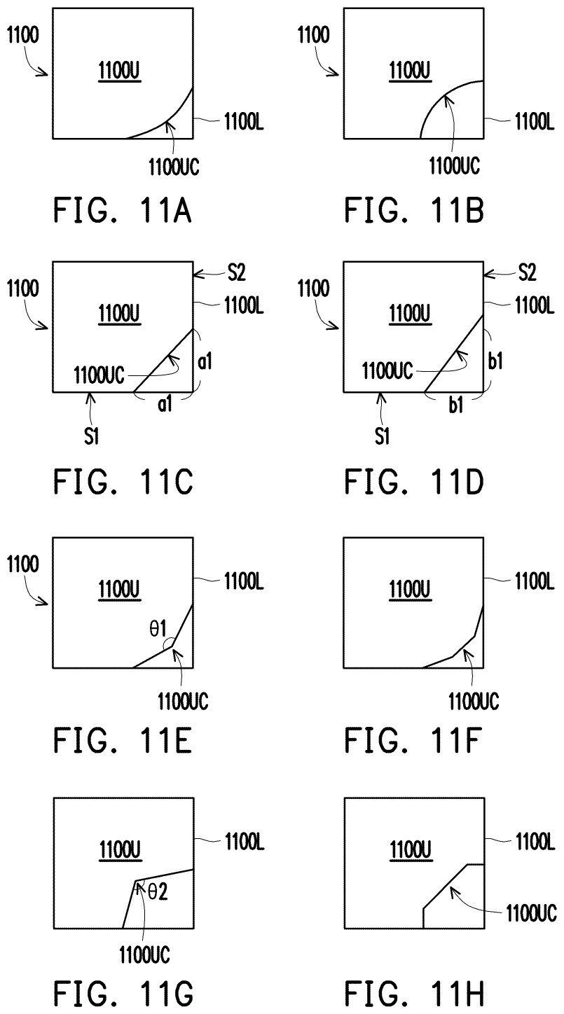

FIGS. 11A-11H are schematic top views of corner portions of the exemplary pruned die structures in accordance with some embodiments of the present disclosure. Relative to the lower remained portion 1100L of the prune die 1100 (e.g. in a rectangular shape), the outline of the corner portion 1100UC of the upper recessed portion 1100U may be trimmed into various shapes depending on the processing requirements. As seen in FIG. 11A, relative to the lower remained portion 1100L of the prune die 1100, the corner portion 1100UC of the upper recessed portion 1100U are rounded, and the outline of the corner portion 1100UC of the upper recessed portion 1100U is in an arc shape. In FIG. 11B, relative to the lower remained portion 1100L of the prune die 1100, the corner portion 1100UC of the upper recessed portion 1100U are reversely rounded, and the outline of the corner portion 1100UC of the upper recessed portion 1100U is in a concave arc shape.

In FIGS. 11C-11H, the corner portion 1100UC of the upper recessed portion 1100U are truncated. For example, in FIG. 11C, the outline of the corner portion 1100UC intersects with the long side S1 and the short side S2 of the lower remained portion 1100L with the same distance a1 (i.e. the exposed lower remained portion 1100L is shaped as an isosceles right triangle). For example, in FIG. 11D, the outline of the corner portion 1100UC intersects with the long side S1 and the short side S2 of the lower remained portion 1100L with different distance a1 and b1 respectively (i.e. the exposed lower remained portion 1100L is shaped as a non-isosceles right triangle). In FIG. 11E, the truncated corner portion 1100UC includes an obtuse angle θ1, and the underlying lower remained portion 1100L exposed by the polygonal truncated corner portion 1100UC is shaped as a concave quadrilateral. In FIG. 11F, the underlying lower remained portion 1100L exposed by the polygonal truncated corner portions 1100UC is shaped as a concave quadrilateral. In FIG. 11G, an obtuse angle θ2 in included between the two adjacent sides of the concavely truncated corner portion 1100UC, and the underlying lower remained portion 1100L exposed by the polygonal truncated corner portion 1100UC is shaped as a quadrilateral. In FIG. 11H, the underlying lower remained portion 1100L exposed by the concavely truncated corner portions 1100UC is shaped as a quadrilateral.

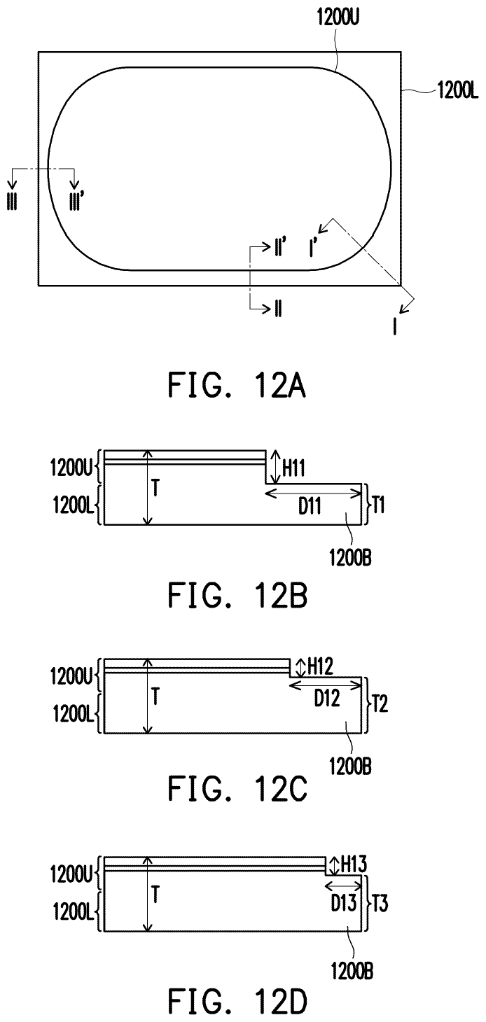

FIG. 12A is a schematic top view of an exemplary pruned die structure after performing a pruning process in accordance with some embodiments of the present disclosure. FIGS. 12B-12D are schematic cross-sectional views of different edge portions of the exemplary pruned die structure(s) cutting along cross-section line I-I′ (along the first direction), cross-section line II-II′ (along the second direction) and cross-section line III-III′ (along the third direction) respectively at three different locations.

Referring to FIG. 12A, after the rectangular semiconductor die 1200 undergoing the pruning process, the contour of the upper recessed portion 1200U is located within the contour of the lower remained portion 1200L, but the upper recessed portion 1200U is recessed from the lower remained portion 1200L with different trimming depths and different trimming distances/widths at various locations. As seen in FIGS. 12B, 12C and 12D, the trimming depth H11 of the first edge portion cutting along the cross-section line I-I′ at the corner part is larger than the trimming depth H12 of the second edge portion cutting along the cross-section line II-II′ at the long side (long side edge), and the trimming depth H12 is larger than or about the same as the trimming depth H13 of the third edge portion cutting along the cross-section line III-III′ at the short side (short side edge). That is, considering the semiconductor die 1200 with a uniform thickness T, the thickness T2 of the brim portion 1200B cutting along the cross-section line II-II′ at long side edge is larger than the thickness T1 of the brim portion 1200B cutting along the cross-section line I-I′ at the corner part, but is smaller than or about the same as the thickness T3 of the brim portion 1200B cutting along the cross-section line III-III′ at the short side edge.

As seen in FIGS. 12B, 12C and 12D, the trimming width D11 of the first edge portion (cutting along the cross-section line I-I′ at the corner part) is larger than the trimming width D12 of the second edge portion (long side edge), and the trimming width D12 is larger than or about the same as the trimming width D13 of the third edge portion (short side edge). That is, the width D12 of the brim portion 1200B cutting along the cross-section line II-II′ at long side edge is smaller than the width D11 of the brim portion 1200B cutting along the cross-section line I-I′ at the corner part, but is larger than or about the same as the width D13 of the brim portion 1200B cutting along the cross-section line III-III′ at the short side edge.

Herein, the above three different regions or locations may be referred to as the first, second and third regions of the die, and the stress of the second region is smaller than the stress of the first region and larger than the stress of the third region, so that the trimming depth/width in the second region is smaller than the trimming depth/width in the first region and larger than the trimming depth/width in the third region. That is, the region that suffers higher stress (e.g. having higher pattern density) and is more deformed or warped should be trimmed (through the pruning process) with a larger trimming depth/width to relieve the warpage and lessen the non-bonding issues caused by warpage or deformity.

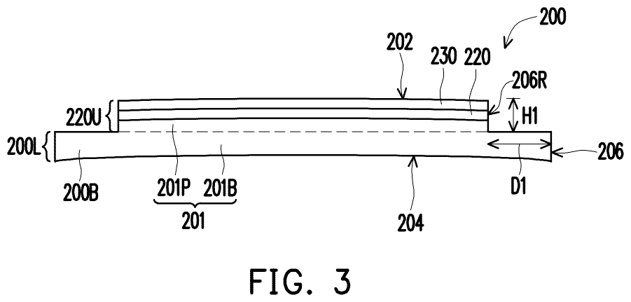

As seen in FIG. 2, in some embodiments, the lower remained portion 200L is wider than the upper recessed portion 200U, and the brim portion 200B is protruded from the body portion 200C, protruding beyond the recessed sidewall(s) 206R of the upper recessed portion 200U with the distance/width D1 (measuring from the recessed sidewall 206R to the sidewall 206 of the brim portion 200B/remained portion 200L). FIG. 3 is a schematic cross-sectional view of the simplified structure of the first die 200, showing the relative configurations of the bonding layer 230, the interconnection structure 220 and the semiconductor substrate 201 without showing details of other elements or devices therein.

In some embodiments, the recessed sidewall(s) 206R of the recessed portion 200U and the sidewall(s) 206 of the brim portion 200B are illustrated as straight or upright planar sidewalls, and the surface 205S connecting the sidewall 206 and the recessed sidewall 206R is illustrated as a flat and level surface. In some embodiments, the sidewall 206R is substantially perpendicular to the surface 205S. In some embodiments, it is possible that the sidewall 206R is slant to the surface 205S. In other embodiments, the recessed sidewall(s) 206R of the recessed portion 200U and the sidewall(s) 206 of the brim portion 200B may be slant or curved sidewall(s). In some embodiments, by fine tuning the conditions of the pruning process, the brim portion 200B may have chamfered edges, beveled edges and/or rounded edges.

As depicted in FIG. 3, in some embodiments, the first die 200 may be slightly deformed and bowed (i.e. convex or a crying-shape from the cross-sectional view), and relative to the central portion of the first die 200, the peripheral portion is the most deformed or warped portion. After performing the pruning process removing the peripheral portion with the height (trimming depth) H1 and the width (trimming distance) D1, the remained portion 200U of the pruned first die 200 is less or minimally deformed with a planarity suitable for bonding. Through performing the pruning process removing the more or most deformed peripheral portion of the die (or other semiconductor structure such as a wafer), the warpage issue is lessened and relieved.

Referring to FIG. 2 and FIG. 3, through the pruning process, the peripheral portion of the first die 200 is partially removed and the first die 200 is pruned or trimmed from the first surface 202 by performing one or more plasma etching processes. In some embodiments, the plasma etching process includes performing one or more reactive ion etching (RIE) processes. In some embodiments, one or more laser grooving processes may be used, and may be performed optionally before or together with the plasma etching process.

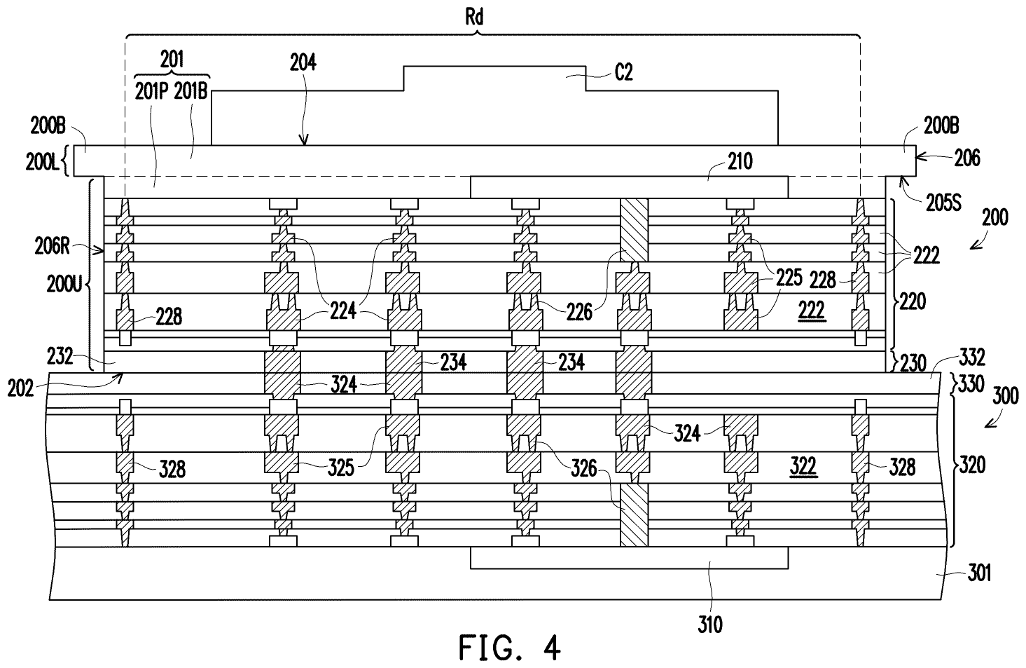

Referring to FIG. 4, a semiconductor structure 300 is provided. In some embodiments, the semiconductor structure 300 is or includes a semiconductor wafer. In some embodiments, the semiconductor structure 300 is or includes one or more semiconductor dies and may be reconstructed as a wafer form or plate form. In some embodiments, the semiconductor structure 300 includes a semiconductor substrate 301, one or more device layers 310 embedded in the semiconductor substrate 301, an interconnection structure 320 formed on the semiconductor substrate 301, and a bonding layer 330 formed on the interconnection structure 320.

In embodiments, the shape of the semiconductor structure 300 may be round or oval, or even rectangular or quadrilateral, and only a portion of the semiconductor structure 300 is shown in the figures for illustration purposes. In some embodiments, the semiconductor structure 300 includes a semiconductor wafer with multiple die units that are defined by the dicing lanes or cutting lines CL (see FIG. 8) and limited within the distribution span of seal ring(s) 328, but only one exemplary die unit is shown in the figures.

In some embodiments, the semiconductor structure 300 is or includes a semiconductor bulk wafer. In some embodiments, the semiconductor structure 300 includes the semiconductor substrate 301 made of a semiconductor material including silicon, strained silicon, silicon alloy, silicon carbide, silicon-germanium, silicon-germanium carbide, germanium, germanium alloys, germanium arsenide, or group III-V semiconductors (e.g. gallium arsenide, gallium nitride, indium arsenide, etc.). In some embodiments, the semiconductor structure 300 is or includes a silicon-on-insulator (SOI) wafer or a gallium arsenide wafer. In some embodiments, the devices formed within the device layer(s) 310 may include, for example, active devices and optionally passive devices or image sensors. In certain embodiments, the devices formed in the device layer(s) 310 may include, for example, transistors. In some embodiments, the interconnection structure 320 is electrically connected with the device layer(s) 310 of the semiconductor structure 300 and is electrically coupled with the devices and/or other electrical components formed within the device layer(s) 310.

In some embodiments, referring to FIG. 4, the interconnection structure 320 includes dielectric layers 322 and conductive patterns 324 alternately stacked. The conductive patterns 324 include routing traces 325 horizontally extending in between stacked dielectric layers 322 and vias 326 vertically penetrating through the dielectric layers 322 to establish electrical connection between the above and underlying routing traces and to the device layer(s) 310. In some embodiments, the interconnection structure 320 includes electrically floating seal rings 328 extending vertically through the dielectric layers 322 and functioning as structural supportive elements for reinforcing the structural rigidity during dicing or cutting. It is understood that the numbers and configurations of the dielectric layers 322 and the conductive patterns 324 are merely exemplary and not intended to limit the scope of this disclosure.

In some embodiments, referring to FIG. 4, the bonding layer 330 includes a bonding dielectric layer 332 and bonding pads 334 embedded in the bonding dielectric layer 332. In some embodiments, some of the bonding pads 334 are electrically connected with the devices formed in the device layers 310 by way of the interconnection structure 320 in the semiconductor structure 300.

FIG. 5 is a schematic cross-sectional view of the simplified structure of the first die 200 stacked on a semiconductor structure 300 as illustrated in FIG. 4 without showing details of other elements or devices within the first die 200 and the semiconductor structure 300.

Referring to FIG. 4 and FIG. 5, in some embodiments, after the first die 200 is pruned by performing the pruning process, the pruned first die 200 is overturned and carried by a carrying chuck or holder C2, and then the pruned first die 200 is stacked upon a provided semiconductor structure 300 with the first surface 202 facing the semiconductor structure 300.

In some embodiments, one or more pruned first dies 200 may be picked, aligned and then placed on the semiconductor structure 300. In some embodiments, with alignment marks embedded in the carrier or the semiconductor structure 300, the arrangement of the pruned first dies 200 is adjusted and aligned so that the bonding pads 234 of the pruned first dies 200 are aligned with and placed directly on the bonding pads 334.

In some embodiments, after mounting the first die 200 onto the semiconductor structure 300, referring to FIGS. 4-5 and FIG. 6, a thermal annealing process is performed to bond the first die 200 and semiconductor structure 300 to form a stacked structure 10. In some embodiments, the first die 200 and the semiconductor structure 300 are bonded though bonding layers 230, 330 at the bonding interface of the first die 200 and the semiconductor structure 300 after bringing the bonding layers 230 and 330 into contact. In some embodiments, the thermal annealing process is performed at temperature ranging from about 100 Celsius degree to about 300 Celsius degree to bond the bonding layers 230, 330 via dielectric-dielectric bonding of the dielectric layers 232, 332 and the metallic-to-metallic bonding of the bonding pads 234, 334 into a stacked structure 10. In some embodiments, it is possible that the stacked structure 10 includes multiple dies 200 and/or includes different types of dies bonded onto the semiconductor structure 300.

Referring to FIG. 6, in some embodiments, the brim portion 200B of the pruned first die 200 overhangs and are protruded from the sidewalls of the recessed portion 200U defining a gap space GS1 between the brim portion 200B, the recessed sidewall 206R and the underlying semiconductor structure 300.

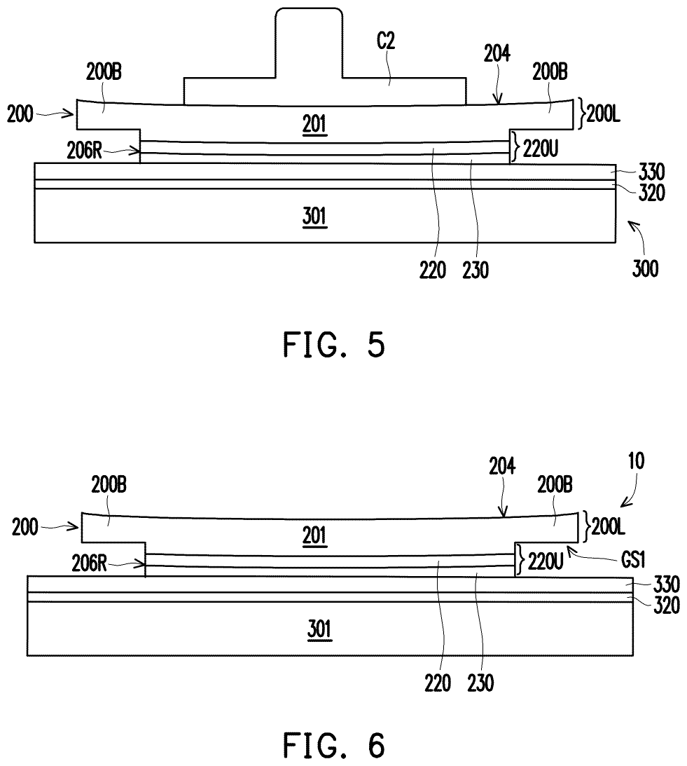

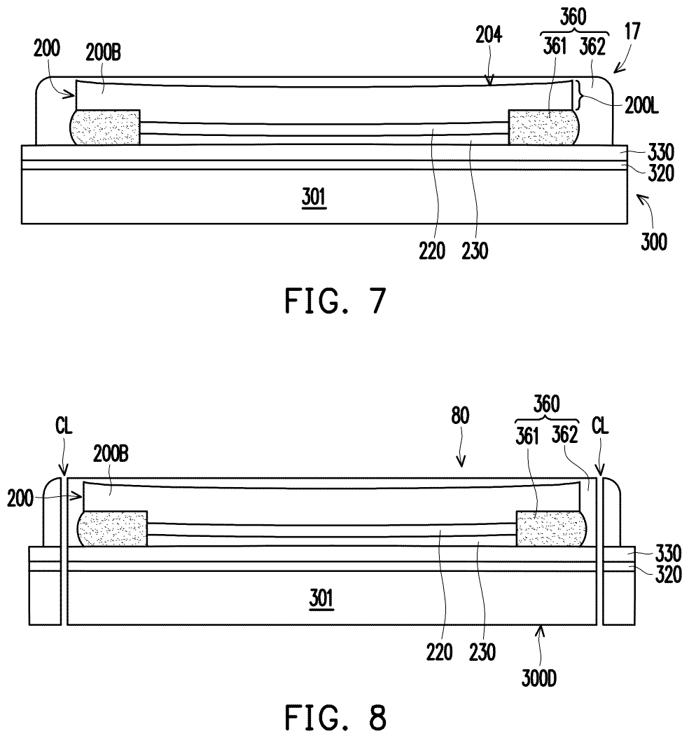

Following the die bonding process, referring to FIG. 7, an enfolding process is performed to form a filling material 360 over the stacked structure 10 covering the pruned first die(s) 200 and covering portions of the semiconductor structure 300. As seen in FIG. 7, the filling material 360 fills into the gap space GS1, wrapping around the recessed portion 200U and fully covering the sidewall(s) 206R, covers the remained portion 200L (at least fully covering the brim portion 200B) and extends beyond the first die 200 and contacts the semiconductor structure 300. In some embodiments, a first material 361 with good gap filling capability is formed to fill the gap space GS1, wrapping around the recessed portion 200U and fully covering the sidewall(s) 206R, and then a second material 362 with medium gap filling capability is formed to cover and wrap around (enfold) the brim portion 200B, to form the enfolded stack structure 17.

In FIG. 7, the sidewall(s) 206R of the recessed portion 200U is fully covered by the first material 361 of the filling material 360, and the later formed second material 362 of the filling material 360 not only covers the brim portion 200B (at least fully covers sidewalls of the brim portion 200B) but also isolates and protects the first material 361.

In some embodiment, as seen in FIG. 7, as the first die 200 is slightly warped (being concave in FIG. 7) or deformed, in order to fully cover (enfold) the brim portion 200B, the filling material 360 is formed to fully cover the surface 204 of the prune first die 200 and the brim portion 200B so that a portion of the filling material 360 is located on the backside surface 204, and the backside surface 204 is not exposed. However, it is understood that if the die is deformed in a convex shape, some of the backside surface of the die may be exposed as long as the brim portion is fully enfolded by the filling material.

In some embodiments, the formation of the filling material 360 through the enfolding process includes forming at least one dielectric material over the first die(s) 200 and covering the exposed portions of the semiconductor structure 300. In some embodiments, the dielectric material may be one or more selected from an oxide material such as silicon oxide, a nitride material such as silicon nitride, silicon oxynitride, a polymeric material such as polyimide, epoxy resins or phenolic resins. In some embodiments, the dielectric material formed by spin-on coating, molding or deposition (such as chemical vapor deposition (CVD)). In some embodiments, the dielectric material may include silicon oxide formed using tetraethyl orthosilicate (TEOS) by CVD (such as plasma enhanced CVD, sub-atmospheric CVD or low-pressure CVD. In some embodiments, the dielectric material may include silicon nitride or silicon oxynitride formed by atomic layer deposition (ALD).

In some embodiments, after performing the enfolding process, the filling material 360 fully covers the first die(s) 200 and covering the exposed portions of the semiconductor structure 300. In some embodiments, a thermal curing process may be optionally performed. In some embodiments, a planarization process may be performed to remove the extra filling material over the first die(s) 200 to reveal the backside surfaces of the first die(s) 200. In some embodiments, during the planarization process, the filling material is polished or grinded until the semiconductor substrates 201 of the first die(s) 200 are exposed. In some embodiments, the planarization process includes performing a mechanical grinding process, a chemical mechanical polishing (CMP) process or the combination thereof.

In some embodiments, the formation of the filling material 360 includes forming a first material 361 that has a good gap filling capability to fill up the gap space GS1 and then a second material 362 that has medium gap filling capability to wrap around and cover the brim portion 200B and the recessed portion 200U. In some embodiments, the materials of the first material 361 and the second material 362 are different. In some embodiments, the first material 361 is less viscous than the second material 362. In some embodiments, the first material includes a dielectric material or a metallic material, and the second material includes a dielectric material. In some embodiments, the metallic material may be copper or copper alloys formed by plating such as electrochemical plating (ECP).

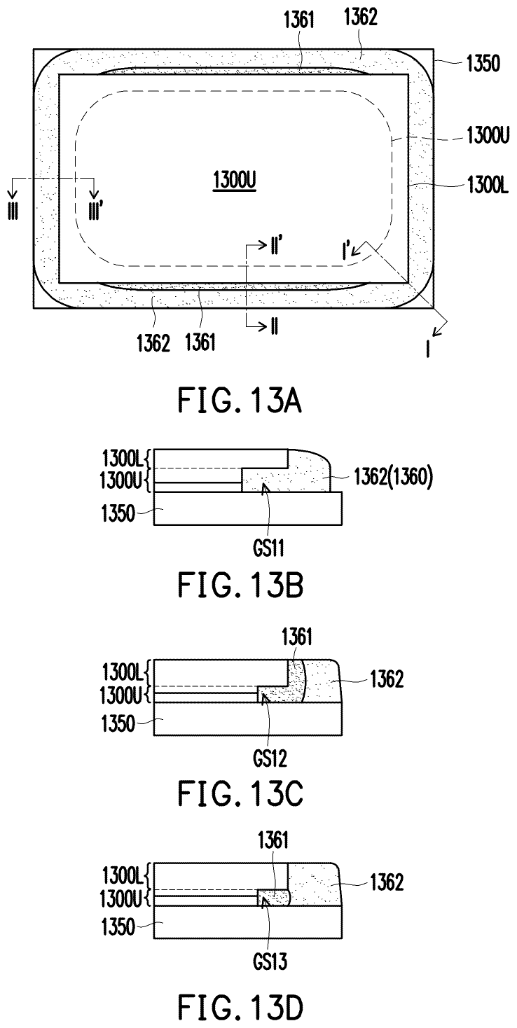

FIG. 13A is a schematic top view of an exemplary enfolded die structure after performing an enfolding process in accordance with some embodiments of the present disclosure. FIGS. 13B-13D are schematic cross-sectional views of different edge portions of the exemplary enfolded die structure cutting along cross-section lines I-I′, II-II′ and III-III′ respectively at three different locations. Referring to FIG. 13A, taking a rectangular semiconductor die 1300 as an example, the contour of the recessed portion 1300U is located within the contour of the remained portion 1300L, but the recessed portion 1300U is recessed from the remained portion 1300L with different trimming depths and different trimming distances/widths at various locations. As the stacked structure of the semiconductor die 1300 bonded onto a bottom semiconductor structure 1350 undergoes the enfolding process, the filling material 1360 including a first material 1361 with good gap filling capability and a second material 1362 with medium gap filling capability is formed over the stack structure.

Among FIGS. 13B, 13C and 13D, the first edge portion at the corner part (cutting along the cross-section line I-I′) is pruned with a larger trimming depth and optionally a larger trimming width, and a larger gap space GS11 exists between the first edge portion and the underlying semiconductor structure 1350 in FIG. 13B. For the second edge portion (long side edge cutting along the cross-section line II-II′) and the third edge portion (short side edge cutting along the cross-section line III-III′), gap spaces GS12 and GS13 exist between the second and third edge portions and the underlying semiconductor structure 1350 respectively as seen in FIG. 13C and FIG. 13D. As the trimming depth and/or trimming width of the second edge portion may be smaller than those of the first edge portion, and the trimming depth and/or trimming width of the third edge portion may be smaller or about the same as those of the second edge portion, the gap spaces GS12 and GS13 are smaller than the gap space GS11. In FIG. 13B, as the gap space GS11 is larger, only a second material 1362 with medium gap filling capability is used, and the second material 1362 fills up the gap space GS11 and overflows outwardly to cover the surface of the underlying semiconductor structure 1350 and fully cover the brim portion 1300B (at least fully covering sidewalls of the brim portion 1300B). In FIG. 13C, the first material 1361 with good gap filling capability fills up the gap space GS12 and overflows to cover the brim portion 1300B, and later the second material 1362 with medium gap filling capability is formed over the stack structure covering the underlying semiconductor structure 1350 and wrapping around the first material 1361. As seen from FIG. 13A, both of the first material 1361 and the second material 1362 are visible near the long side edge portions. In FIG. 13D, the first material 1361 with good gap filling capability is used to fill up the gap space GS13, and later the second material 1362 with medium gap filling capability is formed over the stack structure, covering the underlying semiconductor structure 1350, and fully covering the first material 1361 and the brim portion 1300B (at least fully covering sidewalls of the brim portion 1300B).

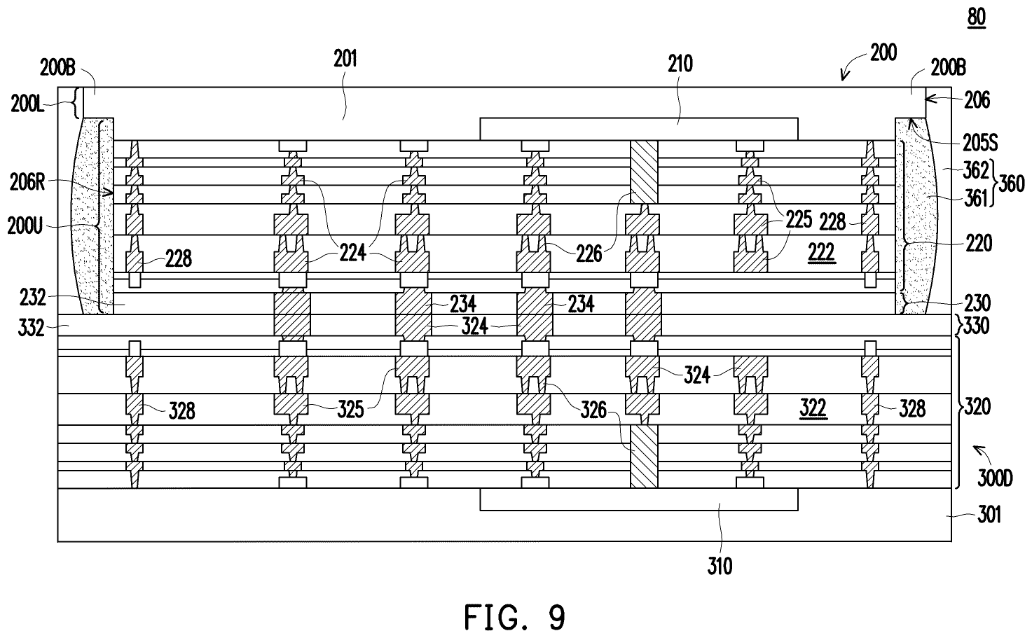

In some embodiments, referring to FIG. 8, a singulation process is performed to cut the enfolded stack structure 17 along the cutting lanes CL into individual three-dimensional (3D) stacking structures 80. In some embodiments, the singulation process includes a dicing process or a sawing process. In exemplary embodiments, in reference to the exemplary arrangement of the semiconductor structure 300, at least one die 300D (i.e. one die unit) is included and defined by the dicing lanes CL as shown in FIG. 8. After singulation, referring to FIG. 8 and FIG. 9, each of the singulated 3D stacking structures 80 includes at least one pruned first die 200 (upper die) stacked on and bonded with the second die 300D (the bottom die) and the filling material 360 laterally wrapping around the first die 200 and covers the top surface of the second die 300D. In some embodiments, the singulation process cutting through the filling material 360 without cutting or damaging the brim portion 200B and cutting the semiconductor structure 300 into second dies 300D. In some embodiments, the singulation process cutting through and cutting off the second material 362 of the filling material 360 without cutting off the first material 361. In some embodiments, the singulation process cutting through and cutting off the second material 362 of the filling material 360 and cutting through and cutting off the first material 361. In some embodiments, the sidewalls of the filling material 360 and the second die 300D are coplanar and vertically aligned.

As seen in FIG. 8 and FIG. 9, for 3D stacking structures 80, the pruned first die 200 is bonded through the recessed portion 200U with the underlying second die 300D, and the recessed portion 200U that is less warped or deformed is in direct contact with and bonded with the underlying second die 300D, thus reliable and better bonding is achieved with no or minimal non-bonding issues. By doing so, the bonding process window is improved and higher yields can be achieved.

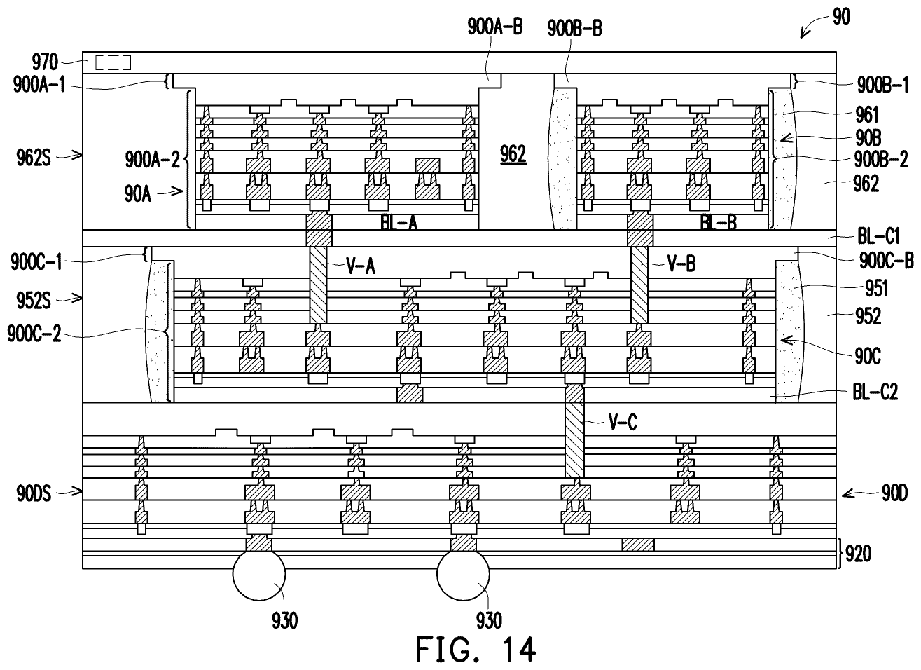

Following the similar processes illustrated from FIG. 1 to FIG. 9, in addition to the bottom die and the upper die(s), more pruned dies of different types may be stacked upon and bonded onto the stack structure. FIG. 14 illustrates a schematic cross-sectional view of a bonded semiconductor structure in accordance with some embodiments of the present disclosure.

As shown in FIG. 14, the semiconductor structure 90 includes a first top die 90A and a second top die 90B stacked on and bonded with the intermediate die 90C, and the bottom die 90D which the intermediate die 90C is stacked upon and bonded with. In some embodiments, either of the intermediate die 90C, the first top die 90A or the second top die 90B is similar to the pruned first die 200 that is processed with the pruning process and as described in the previous context. In some embodiments, the intermediate die 90C is provided with a first portion 900C-1 and a second portion 900C-2 recessed from the first portion 900C-1, and the first portion 900C-1 also includes a brim portion 900C-B extended and protruded from the second portion 900C-2. Similarly, the first top die 90A is provided with a first portion 900A-1 and a second portion 900A-2 recessed from the first portion 900A-1, and the first portion 900A-1 also includes a brim portion 900A-B extended and protruded from the second portion 900A-2. Also, the second top die 90B is provided with a first portion 900B-1 and a second portion 900B-2 recessed from the first portion 900B-1, and the first portion 900B-1 also includes a brim portion 900B-B extended and protruded from the second portion 900B-2. In some embodiments, the bottom die 90D is similar to the second die 300D that are obtained from the semiconductor structure 300 through later singulation as described in the previous contexts.

In FIG. 14, after the intermediate die 90C is bonded onto the bottom die 90D, a first filling material 951 is firstly formed to wrapped the recessed second portion 900C-2 and later a second filling material 952 is formed to enfold the intermediate die 900C, especially enfolding the brim portion 900C-B. Later, supported by a semiconductor structure (e.g. a carrying wafer) 970 with alignment marks (shown as dotted line square) embedded therein for alignment, the top dies 90A and 90B that are aligned and arranged side-by-side are bonded onto the intermediate die 90C. Afterwards, a third filling material 961 is formed to wrapped the recessed second portion 900B-2, and then a fourth filling material 962 is formed over the stack structure, filling up the spaces between the first and second top dies 90A, 90B and wrapping around the first and second top dies 90A, 90B (at least fully covering the brim portions 900A-B and 900B-B). Afterwards, a singulation process is performed to obtain the semiconductor structure 90. In some embodiments, the first filling material 951 is different from the second filling material 952, while the third filling material 961 is different from the fourth filling material 962. In some embodiments, the first filling material 951 has a gap filling capability better than that of the second filling material 952. In some embodiments, the third filling material 961 has a gap filling capability better than that of the fourth filling material 962.

In some embodiments, referring to FIG. 14, the first and second top dies 90A, 90B are bonded with the intermediate die 90C through the bonding layers BL-A, BL-B and BL-C1, and are electrically connected with the intermediate die 90C by way of at least through semiconductor vias V-A and V-B. In some embodiments, the intermediate die 90C is bonded with the bottom die 90D through the bonding layer BL-C2, and electrically connected with the bottom die 90D by way of at least through semiconductor vias V-C. In FIG. 14, the semiconductor structure 90 further includes redistribution structure 920 formed on the bottom surface of the bottom die 90D and bump connectors 930 formed on the redistribution structure 920 for further electrical connection. For the bottom die 90D, the sidewalls 90DS of the bottom die 90D are exposed without being covered by the filling material, but the sidewalls 90DS of the bottom die 90D are coplanar with and vertically aligned with the sidewalls 952S of the second filling material 952 and the sidewalls 962S of the fourth filling material 962.

In accordance with the present disclosure, the pruning process performed to the semiconductor structure removes the more or most deformed edge portions that are more stressful before bonding. In other words, the edge portions that may lead to non-bonding at the periphery of the large size die or wafer structure are removed by the pruning process. The pruning process etches off the edge portions, and the device layers of the dies will not be damaged, inferior bonding is lowered and the product yield is increased. Based on the above, by performing the pruning process, larger process window and higher operation efficiency are offered.

According to some embodiments, a semiconductor structure including a first semiconductor structure, a second semiconductor structure, and a filling material is disclosed. The first semiconductor structure has a first surface and a second surface opposite to the first surface. The first semiconductor structure has a body portion and a semiconductor brim portion protruded from the body portion. The semiconductor brim portion is closer to the second surface. The second semiconductor structure is in contact with the first surface of the first semiconductor structure and bonded with the first semiconductor structure. The filling material surrounds the first semiconductor structure and is filled between the semiconductor brim portion and the second semiconductor structure. The filling material wraps around and covers the semiconductor brim portion, and a sidewall of the filling material is aligned with a sidewall of the second semiconductor structure.

According to some alternative embodiments, a semiconductor structure, including a bottom semiconductor structure, a first semiconductor structure, a second semiconductor structure, and a first and a second filling materials is disclosed. The first semiconductor structure is stacked on and bonded with the bottom semiconductor structure. The first semiconductor structure includes a first semiconductor substrate, and a first brim portion of the first semiconductor substrate protruded from a first recessed portion of the first semiconductor structure. The second semiconductor structure is stacked on and bonded with the first semiconductor structure. The second semiconductor structure includes a second semiconductor substrate, and a second brim portion of the second semiconductor substrate protruded from a second recessed portion of the second semiconductor structure. The first filling material surrounds the first semiconductor structure and is filled between the first brim portion and the bottom semiconductor structure. The first filling material wraps around the first brim portion and covers the first semiconductor structure. The second filling material surrounds the second semiconductor structure and is filled between the second brim portion and the first semiconductor structure. The second filling material wraps around the second brim portion and covers the second semiconductor structure. Sidewalls of the first filling material, sidewalls of the second filling material and sidewalls of the bottom semiconductor structure are vertically aligned.

According to some alternative embodiments, a manufacturing method of a semiconductor structure includes the following steps. A first semiconductor structure having a first surface and a second surface opposite to the first surface is provided. A pruning process is performed to the first semiconductor structure, partially removing a portion of the first semiconductor structure from the first surface to form a pruned first semiconductor structure with a body portion and a brim portion protruded from the body portion. The brim portion is closer to the second surface. A second semiconductor structure is provided. The pruned first semiconductor structure is bonded to the second semiconductor structure to form a bonded structure. The first surface of the pruned first semiconductor structure contacts the second semiconductor structure, and a gap space exists between the brim portion and the second semiconductor structure of the bonded structure. An enfolding process is performed by forming a filling material over the bonded structure to cover the pruned first semiconductor structure, fill the gap space and wrap around the brim portion to form an enfolded structure. A singulation process is performed to the enfolded structure cutting through the filling material and the second semiconductor structure to form a semiconductor stack. A sidewall of the filling material is aligned with a sidewall of the singulated second semiconductor structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first semiconductor structure having a first surface and a second surface opposite to the first surface, wherein the first semiconductor structure has a body portion and a semiconductor brim portion protruded from the body portion, wherein the semiconductor brim portion is closer to the second surface;
a second semiconductor structure, in contact with the first surface of the first semiconductor structure and bonded with the first semiconductor structure; and
a filling material, surrounding the first semiconductor structure and filled between the semiconductor brim portion and the second semiconductor structure,
wherein the filling material wraps around and covers the semiconductor brim portion, and a sidewall of the filling material is aligned with a sidewall of the second semiconductor structure.

2. The structure according to claim 1, wherein the first semiconductor structure includes a first semiconductor substrate, a first interconnection structure and a first bonding layer, and a recessed portion of the body portion includes the first interconnection structure and the first bonding layer and a portion of the first semiconductor substrate.

3. The structure according to claim 1, wherein the first semiconductor structure includes a first semiconductor substrate, a first interconnection structure and a first bonding layer, and a recessed portion of the body portion includes only the first interconnection structure and the first bonding layer.

4. The structure according to claim 1, wherein the filling material includes a first filling material disposed on the body portion and surrounding the first semiconductor structure, and a second filling material covering the first filling material, wherein the first filling material has a gap filling capability higher than that of the second filling material.

5. The structure according to claim 4, wherein the semiconductor brim portion includes a first portion of a first protrusion width and a second portion of a second protrusion width smaller than the first protrusion width, and the first portion contacts the second filling material, and the second portion contacts the first and second filling materials.

6. The structure according to claim 5, wherein the semiconductor brim portion further includes a third portion of a third protrusion width larger than the second protrusion width and smaller than the first protrusion width, and the third portion contacts the first filling material.

7. The structure according to claim 4, wherein the semiconductor brim portion includes a first portion of a first thickness and a second portion of a second thickness larger than the first thickness, and the first portion contacts the second filling material, and the second portion contacts the first and second filling materials.

8. The structure according to claim 7, wherein the semiconductor brim portion further includes a third portion of a third thickness smaller than the second thickness and larger than the first thickness, and the third portion contacts the first filling material.

9. A semiconductor structure, comprising:
a bottom semiconductor structure;
a first semiconductor structure, stacked on and bonded with the bottom semiconductor structure, wherein the first semiconductor structure includes a first semiconductor substrate, and a first brim portion of the first semiconductor substrate protruded from a first recessed portion of the first semiconductor structure;
a second semiconductor structure, stacked on and bonded with the first semiconductor structure, wherein the second semiconductor structure includes a second semiconductor substrate, and a second brim portion of the second semiconductor substrate protruded from a second recessed portion of the second semiconductor structure;
a first filling material, surrounding the first semiconductor structure and filled between the first brim portion and the bottom semiconductor structure, wherein the first filling material wraps around the first brim portion and covers the first semiconductor structure; and
a second filling material, surrounding the second semiconductor structure and filled between the second brim portion and the first semiconductor structure, wherein the second filling material wraps around the second brim portion and covers the second semiconductor structure,
wherein sidewalls of the first filling material, sidewalls of the second filling material and sidewalls of the bottom semiconductor structure are vertically aligned.

10. The structure according to claim 9, wherein the first brim portion is in a ring shape surrounding the first recessed portion.

11. The structure according to claim 10, wherein the second brim portion includes four corner portions protruded from the second recessed portion.

12. The structure according to claim 9, wherein the first semiconductor structure includes a first interconnection structure with a first seal ring located on the first semiconductor substrate, and a contour of the first recessed portion from a top view is located outside a span of the first seal ring.

13. The structure according to claim 9, wherein the second semiconductor structure includes a second interconnection structure with a second seal ring located on the second semiconductor substrate, and a contour of the first recessed portion from a top view is located outside a span of the first seal ring.

14. A manufacturing method of a semiconductor structure, comprising:
providing a first semiconductor structure having a first surface and a second surface opposite to the first surface;
performing a pruning process to the first semiconductor structure and partially removing a portion of the first semiconductor structure from the first surface to form a pruned first semiconductor structure with a body portion and a brim portion protruded from the body portion, wherein the brim portion is closer to the second surface;
providing a second semiconductor structure;
bonding the pruned first semiconductor structure to the second semiconductor structure to form a bonded structure, wherein the first surface of the pruned first semiconductor structure contacts the second semiconductor structure, and a gap space exists between the brim portion and the second semiconductor structure of the bonded structure;
performing an enfolding process by forming a filling material over the bonded structure to cover the pruned first semiconductor structure, fill the gap space and wrap around the brim portion to form an enfolded structure; and
performing a singulation process to the enfolded structure cutting through the filling material and the second semiconductor structure to form a semiconductor stack, wherein a sidewall of the filling material is aligned with a sidewall of the singulated second semiconductor structure.

15. The method according to claim 14, wherein performing a pruning process includes performing one or more plasma etching processes.

16. The method according to claim 14, wherein the singulation process cuts through the filling material without cutting the brim portion of the pruned first semiconductor structure.

17. The method according to claim 14, wherein forming a filling material over the bonded structure includes forming a first filling material to fill the gap space and forming a second filling material to wrap around the brim portion and cover the pruned first semiconductor structure.

18. The method according to claim 14, wherein forming a filling material over the bonded structure includes forming a first filling material to fill the gap space and wrap around the brim portion and forming a second filling material to cover the pruned first semiconductor structure.

19. The method according to claim 14, wherein the first semiconductor structure is provided with a semiconductor substrate, an interconnection structure and a bonding layer, and the pruning process removes a portion of the semiconductor substrate, a portion of the interconnection structure and a portion of the bonding layer.

20. The method according to claim 14, wherein the first semiconductor structure is provided with a semiconductor substrate, an interconnection structure and a bonding layer, and the pruning process removes a portion of the interconnection structure and a portion of the bonding layer.
